(19) United States
(12) Patent Application Publication
(10) Pub. No.: US 2024/0304735 A1
(43) Pub. Date: Sep. 12, 2024

(54) OPTOELECTRONIC SEMICONDUCTOR COMPONENT, AND METHOD FOR PRODUCING THE OPTOELECTRONIC SEMICONDUCTOR COMPONENT

(71) Applicant: ams-OSRAM International GmbH, Regensburg (DE)

(72) Inventor: Michael ZITZLSPERGER, Regensburg (DE)

(73) Assignee: ams-OSRAM International GmbH, Regensburg (DE)

(21) Appl. No.: 18/272,070

(22) PCT Filed: Dec. 22, 2021
(86) PCT No.: PCT/EP2021/087259

§ 371 Date: Jul. 12, 2023

(30) Foreign Application Priority Data
Jan. 13, 2021 (DE) 102021100530.2

(51) Int. Cl. H01L 31/0203; H01L 31/0232; H01L 31/18; H01L 33/00; H01L 33/48; H01L 33/58

(52) U.S. Cl. CPC H01L 31/0203; H01L 31/02325; H01L 31/186; H01L 33/0095; H01L 33/483; H01L 33/58; H01L 2933/0058

(57) ABSTRACT

Aspects relate to an optoelectronic semiconductor component comprising a semiconductor body having an optically active region designed to emit or detect electromagnetic radiation, a support, a molded body, and a prefabricated optical shielding with a support structure and a diaphragm. The semiconductor body and the molded body are arranged on the front face of the support. The molded body at least partly surrounds the semiconductor body in a lateral direction, and the optical shielding is arranged on the molded body face facing away from the support and projects beyond the molded body in the lateral direction in the direction of the semiconductor body. The diaphragm has an opening which is oriented towards the optically active region. Additionally, an insulating structure is arranged adjacently to the semiconductor body, the insulating structure at least partly surrounding the semiconductor body. Aspects also relate to a method for producing the optoelectronic semiconductor component.

An optoelectronic semiconductor component and a method for producing an optoelectronic semiconductor component are specified.

This patent application claims the priority of German patent application 10 2021 100 530.2, the disclosure content of which is hereby incorporated by reference.

The optoelectronic semiconductor component is configured in particular for generating and/or detecting electromagnetic radiation, preferably light perceptible to the human eye.

One object to be achieved consists in specifying an optoelectronic semiconductor component having an improved durability.

A further object to be achieved consists in specifying a method for simplified production of an optoelectronic semiconductor component having an improved durability.

In accordance with at least one embodiment, the optoelectronic semiconductor component comprises a semiconductor body having an optically active region configured for emitting or detecting electromagnetic radiation.

The semiconductor body comprises in particular a plurality of layers of a semiconductor material grown epitaxially one on top of another. The layers are deposited one on top of another in a stacking direction. The stacking direction thus runs transversely, in particular perpendicularly, with respect to a main extension direction of the semiconductor body. By way of example, the semiconductor body is a monolithically embodied semiconductor crystal.

Furthermore, the semiconductor body comprises an optically active region configured for emitting or detecting electromagnetic radiation. In particular, the optically active region has a pn junction, a double heterostructure, a single quantum well (SQW) structure or a multiquantum well (MQW) structure for generating radiation or for detecting radiation. The semiconductor component is for example a photodiode or a luminescent diode, in particular a light emitting diode or a laser diode.

The semiconductor body has a main surface on a side of the semiconductor body facing away from the carrier. In particular, the main surface of the semiconductor body is configured to allow electromagnetic radiation to emerge from the semiconductor body or to allow it to enter the semiconductor body.

In accordance with at least one embodiment of the optoelectronic semiconductor component, the optoelectronic semiconductor component comprises a carrier. In particular, a sufficient mechanical stability of the semiconductor component is attained by means of the carrier. Furthermore, the carrier can serve as a mounting platform for the semiconductor body. Preferably, the carrier comprises a plurality of electrical contact structures via which the semiconductor body is connected. By way of example, the carrier is formed with a polymer or a ceramic material.

By way of example, the optoelectronic semiconductor component comprises an additional control element. The control element preferably comprises an integrated circuit having a plurality of circuit elements and is configured in particular for electrically controlling the semiconductor body. Preferably, the control element is arranged between the semiconductor body and the carrier. The semiconductor body is preferably arranged on a side of the control element facing away from the carrier. The control element enables a particularly compact design of a controllable semiconductor component.

In accordance with at least one embodiment of the optoelectronic semiconductor component, the optoelectronic semiconductor component comprises a molded body. The molded body is formed with a mold material, for example. The molded body is preferably producible by means of compression molding or transfer molding. In particular, the molded body protects the semiconductor body against external environmental influences.

In accordance with at least one embodiment of the optoelectronic semiconductor component, the optoelectronic semiconductor component comprises a prefabricated optical shield comprising a support structure and a diaphragm. Radiation-sensitive regions of the optoelectronic semiconductor component can be protected against incident electromagnetic radiation by means of the optical shield. This advantageously gives rise to an optoelectronic semiconductor component having an improved durability.

The support structure serves for stabilizing the optical shield. By way of example, the support structure is formed with a polymer material. The diaphragm defines a region of the optoelectronic semiconductor component in which electromagnetic radiation can enter the semiconductor component or can emerge from the semiconductor component. By way of example, the diagram is formed with a metal or a metal alloy.

In particular, the support structure and the diaphragm are already connected to one another in the prefabricated optical shield. This simplifies mounting of the optical shield in the optoelectronic semiconductor component. By way of example, a plurality of optical shields are provided in a common composite assembly.

In accordance with at least one embodiment of the optoelectronic semiconductor component, the semiconductor body and the molded body are arranged on a front side of the carrier. Preferably, the molded body projects beyond the semiconductor body in a direction parallel to the stacking direction of the semiconductor body. In this regard, the molded body can protect the semiconductor body against mechanical damage.

A mounting surface for the semiconductor body is preferably provided on the front side of the carrier. A further mounting surface configured for mounting the optoelectronic semiconductor component is preferably provided on a rear side of the carrier, opposite the front side.

In accordance with at least one embodiment of the optoelectronic semiconductor component, the molded body at least partly surrounds the semiconductor body in a lateral direction. The lateral direction runs parallel to a main extension plane of the carrier and of the semiconductor body and thus transversely, in particular perpendicularly, with respect to the stacking direction of the semiconductor body. A molded body that surrounds the semiconductor body in a lateral direction can protect the semiconductor body against mechanical influences from the lateral direction.

In particular, the molded body completely surrounds the semiconductor body in a lateral direction. A molded body completely surrounding the semiconductor body laterally has an advantageously increased mechanical stability. As a result, the semiconductor body is even better protected against mechanical influences.

In accordance with at least one embodiment of the optoelectronic semiconductor component, the optical shield is arranged on a side of the molded body facing away from the carrier and projects beyond the molded body in the lateral direction in the direction of the semiconductor body.

The optical shield is thus arranged in such a way that it lies in the beam path of the semiconductor body. In other words, electromagnetic radiation that is emitted or detected by the semiconductor body passes the optical shield in each case.

The optical shield projects beyond the semiconductor body in the lateral direction in the direction of the semiconductor body preferably in such a way that electromagnetic radiation emitted or detected by the semiconductor body during operation is shaded as little as possible.

In accordance with at least one embodiment of the optoelectronic semiconductor component, the diaphragm has an opening aligned with the optically active region. In particular, the opening of the diaphragm is aligned with the optically active region in a plan view.

An alignment of the opening with the optically active region can advantageously reduce or avoid shading of radiation emitted from the optically active region during operation or of electromagnetic radiation detected in the optically active region during operation.

In accordance with at least one embodiment of the optoelectronic semiconductor component, the optoelectronic semiconductor component comprises:
a semiconductor body having an optically active region configured for emitting or detecting electromagnetic radiation,
a carrier,
a molded body, and
a prefabricated optical shield comprising a support structure and a diaphragm, wherein
the semiconductor body and the molded body are arranged on a front side of the carrier,
the molded body at least partly surrounds the semiconductor body in a lateral direction,
the optical shield is arranged on a side of the molded body facing away from the carrier and projects beyond the molded body in the lateral direction in the direction of the semiconductor body,
the diaphragm has an opening aligned with the optically active region.

An optoelectronic semiconductor component described here is based on the following considerations, inter alia: some elements of an optoelectronic semiconductor component have a low tolerance vis-à-vis exposure to electromagnetic radiation. It is therefore advantageous for particularly radiation-sensitive regions of the optoelectronic semiconductor component to be shielded from electromagnetic radiation.

In particular, optoelectronic semiconductor components provided for use in a motor vehicle headlight are subjected to very high irradiation both as a result of incidence of solar radiation and as a result of internal reflections during operation of the component.

The optoelectronic semiconductor component described here makes use of the concept, inter alia, of integrating a prefabricated optical shield in an optoelectronic semiconductor component. The particularly radiation-sensitive regions of the optoelectronic semiconductor component can be shielded by means of the optical shield. The optical shield can be arranged such that it has as little adverse effect as possible on emission or detection of electromagnetic radiation during operation of the semiconductor component.

In accordance with at least one embodiment of the optoelectronic semiconductor component, the optical shield comprises a protective layer arranged on a side of the optical shield facing away from the molded body. By means of the protective layer, the optical shield itself can be protected against external environmental influences. In particular, the protective layer is nontransmissive to electromagnetic radiation in the spectral range of solar radiation. By way of example, the protective layer is embodied in black or white fashion. A black protective layer has a particularly low reflectivity and thus minimizes disturbing reflections that possibly occur, while a white protective layer has a particularly high reflectivity and can thus reduce heating of the component.

The optical shield protects radiation-sensitive parts of the optoelectronic semiconductor component against externally incident electromagnetic radiation and against electromagnetic radiation emitted in the semiconductor body during operation. In particular, the protective layer is arranged only on the support structure. The support structure is formed with a radiation-sensitive material, for example.

In accordance with at least one embodiment of the optoelectronic semiconductor component, the protective layer mechanically connects the optical shield to the molded body. By way of example, the protective layer thus also performs the function of an adhesive layer or a connecting layer. Consequently, an additional adhesive or connecting layer is advantageously not necessary.

In accordance with at least one embodiment of the optoelectronic semiconductor component, the protective layer is formed with a polysiloxane. A polysiloxane is particularly thermally stable, for example, and has advantageously good adhesion on various materials. Preferably, the protective layer comprises a radiation-nontransmissive filling material. By way of example, the protective layer is formed with a blackened silicone.

In accordance with at least one embodiment of the optoelectronic semiconductor component, the optical shield is incorporated in the molded body in a vertical direction. The vertical direction runs transversely, in particular perpendicularly, with respect to the lateral direction. Preferably, the optical shield is incorporated into the molded body in a flush manner. This advantageously thus results in a planar surface of the optoelectronic semiconductor component. Here and hereinafter, planar means a surface which is embodied in flat fashion, within the scope of a production tolerance.

The surface of the optoelectronic semiconductor component is the side of the optoelectronic semiconductor component facing away from the carrier. A planar surface facilitates a further arrangement of components on the surface, for example.

In accordance with at least one embodiment of the optoelectronic semiconductor component, a dam structure is arranged next to the semiconductor body in the lateral direction, and at least partly surrounds the semiconductor body. In particular, the dam structure projects beyond the semiconductor body in a vertical direction.

Preferably, the dam structure is formed with a radiation-nontransmissive material. By way of example, the dam structure prevents the optical shield from directly touching the main surface of the semiconductor body. Furthermore, the dam structure can be configured to protect bonding wires arranged on or next to the semiconductor body against mechanical damage.

Part of electromagnetic radiation emitted or detected in the optically active region can be shaded by means of the dam structure. In this regard, the dam structure can protect the optical shield and the molded body against electromagnetic radiation.

Preferably, the dam structure forms a closed ring. In this regard, the dam structure can form particularly good protection against electromagnetic radiation.

In accordance with at least one embodiment of the optoelectronic semiconductor component, the dam structure touches a side of the optical shield facing the carrier. Preferably, across its entire extension the dam structure touches the side of the optical shield facing the carrier. Particularly good shielding of the molded body and of the optical shield is possible as a result. In particular, the dam structure touches the diaphragm. In this regard, complete protection of the support structure against electromagnetic radiation can be ensured.

A dam structure that touches the optical shield advantageously increases a mechanical stability of the optical shield and additionally provides further shielding for the support structure and the molded body against electromagnetic radiation.

In accordance with at least one embodiment of the optoelectronic semiconductor component, the dam structure is formed with a polysiloxane. A polysiloxane can be arranged on a semiconductor body particularly simply and reliably and has a high thermal stability. In particular, the dam structure is formed with a blackened silicone. The protective layer and the dam structure are preferably formed with the same material. This enables particularly simple production of the protective layer and the dam structure.

In accordance with at least one embodiment of the optoelectronic semiconductor component, the carrier, the molded body and the optical shield form a housing for the optoelectronic semiconductor component. A housing surrounds the semiconductor body on all sides, with the exception of the opening. The housing protects the optoelectronic component against external environmental influences. Furthermore, a housing can facilitate further handling and subsequent mounting of the optoelectronic semiconductor component.

In accordance with at least one embodiment of the optoelectronic semiconductor component, at least one side surface of the optoelectronic semiconductor component is planar. A side surface of the semiconductor component is composed for example of partial surfaces of the carrier, of the molded body, of the support structure and of the protective layer. The optoelectronic semiconductor component is delimited by the side surface in terms of its lateral extent.

A planar side surface facilitates gripping of the optoelectronic semiconductor component, for example. In particular, components having planar side surfaces can be arranged next to one another with a particularly small lateral spacing. A plurality of optoelectronic semiconductor components can thus be arranged on a particularly small mounting surface.

In accordance with at least one embodiment of the optoelectronic semiconductor component, the support structure is multipartite and comprises a first support element and a second support element. The first support element is adhesively bonded to the second support element, for example. Preferably, a multipartite composite assembly composed of a plurality of elements has a higher mechanical stability than a single element. Single elements can each be optimized toward a specific purpose of use. By way of example, the first support element has particularly good adhesion to the diaphragm, while the second support element has a particularly high thermal stability.

In accordance with at least one embodiment of the optoelectronic semiconductor component, the first support element is formed with an epoxy composite material. An epoxy composite material is a preferred material, for example in the production of QFN leadframes, and is therefore easy to procure and allows good processing using known methods. Advantageously, an epoxy composite material has a high mechanical stability and a low inherent weight. That makes it possible to form a support structure having an advantageously particularly small extent in the vertical direction.

In accordance with at least one embodiment of the optoelectronic semiconductor component, the second support element is formed with a printed circuit board material. A printed circuit board material is, in particular, a fiber-reinforced composite material. Preferably, the printed circuit board material comprises a glass fiber-reinforced epoxy resin. By way of example, the printed circuit board material is formed with FR4 composite material. The printed circuit board material is advantageously particularly thermally stable and has a high mechanical strength. It is further advantageous that the printed circuit board material has a high adhesiveness for copper, and thus enables a diaphragm formed with copper to be mechanically secured to the support structure particularly reliably.

In accordance with at least one embodiment of the optoelectronic semiconductor component, the diaphragm is formed with copper. By way of example, the diaphragm is part of a prefabricated leadframe, preferably of a QFN leadframe, or is formed from a prefabricated leadframe, preferably a QFN leadframe. A diaphragm formed with copper is advantageously producible with clearly defined edges. A diaphragm with a clearly defined edge that is thinned in one region in the direction of the opening advantageously causes particularly little shading of radiation passing through. In particular, the diaphragm comprises a coating to withstand external environmental influences, such as oxidation, for example. The coating comprises nickel, palladium and gold, for example. By way of example, the coating completely covers the outer surfaces of the diaphragm. Preferably, the diaphragm is formed with passivated copper having a reduced optical reflectivity.

In accordance with at least one embodiment of the optoelectronic semiconductor component, the diaphragm has an extent in the vertical direction of at least 50 μm and at most 500 μm, preferably of at least 100 μm and at most 250 μm. A vertical extent that is as small as possible produces a particularly thin diaphragm that advantageously particularly minimizes shading of electromagnetic radiation passing through it. However, the diaphragm advantageously has a sufficiently large vertical extent in order to ensure a mechanical stability.

In accordance with at least one embodiment of the optoelectronic semiconductor component, the diaphragm, on a side facing away from the carrier, has a projection above the support structure in a vertical direction. In particular, the projection extends over at least 30 μm. A projection embodied in this way enables the diaphragm to delimit a lateral extent of a protective layer.

In accordance with at least one embodiment of the optoelectronic semiconductor component, a diameter of the opening in the diaphragm increases or decreases with the distance with respect to the semiconductor body. In other words, the opening has a conical shape. In particular, the opening has the shape of a truncated cone or of a truncated pyramid.

By way of example, the opening tapers in the direction of the semiconductor body. An opening configured in this way produces a diaphragm having an enlarged aperture and thus reduces or avoids shading of electromagnetic radiation passing through it.

In accordance with at least one embodiment of the optoelectronic semiconductor component, the optical shield is nontransmissive to electromagnetic radiation generated or detected in the active region during operation. In conjunction with the dam structure, radiation-sensitive parts of the semiconductor component can thus be protected against electromagnetic radiation generated in the semiconductor body during operation. In particular, the shield also protects further components arranged in the surroundings against electromagnetic radiation generated in the semiconductor body during operation.

Furthermore, a method for producing an optoelectronic semiconductor component is specified. The optoelectronic component can be produced in particular by means of a method described here. In other words, all features disclosed in connection with the method for producing an optoelectronic semiconductor component are also disclosed for the optoelectronic semiconductor component, and vice versa.

In accordance with at least one embodiment of the method for producing an electronic semiconductor component, step A) involves providing a carrier together with a semiconductor body having an optically active region configured for emitting or detecting electromagnetic radiation, and together with a molded body on a front side of the carrier. In particular, a plurality of semiconductor bodies and molded bodies are provided on a common carrier.

In accordance with at least one embodiment of the method for producing an optoelectronic semiconductor component, step B) involves arranging a prefabricated optical shield comprising a support structure and a diaphragm on a side of the molded body facing away from the carrier, the diaphragm having an opening aligned with the optically active region. The alignment of the opening with the optically active region is effected for example in a plan view of the optoelectronic semiconductor component.

Arranging an already prefabricated optical shield enables particularly fast and efficient production of the optoelectronic semiconductor component. As a result, a complex method step for producing the opening in the diaphragm can be implemented beforehand in a separate method step with a particularly high accuracy.

By way of example, a plurality of prefabricated optical shields in a common composite assembly are arranged on a plurality of semiconductor bodies in the molded body on a common carrier. Advantageously, a plurality of openings can thus be aligned with a plurality of optically active regions in a single step. By way of example, a plurality of individual optoelectronic semiconductor components are provided by means of a subsequent singulation step.

In accordance with at least one embodiment of the method for producing an optoelectronic semiconductor component, a further step C) involves applying a protective layer on a side of the optical shield facing away from the carrier. The protective layer is preferably applied by means of dispensing. If the diaphragm has a projection in a vertical direction, the diaphragm can advantageously delimit a lateral extent of the protective layer.

In accordance with at least one embodiment of the method for producing an optoelectronic semiconductor component, step B) is preceded by arranging a dam structure next to the semiconductor body (10) in the lateral direction (X). Prior to arranging the prefabricated optical shield in step B), an arrangement of the dam structure is advantageously facilitated. The dam structure is preferably arranged by means of dispensing.

An optoelectronic semiconductor component described here is suitable in particular for use in a motor vehicle headlight or a projection application outdoors.

Further advantages and advantageous configurations and developments of the optoelectronic semiconductor component will become apparent from the following exemplary embodiments in association with those illustrated in the figures.

In the figures:

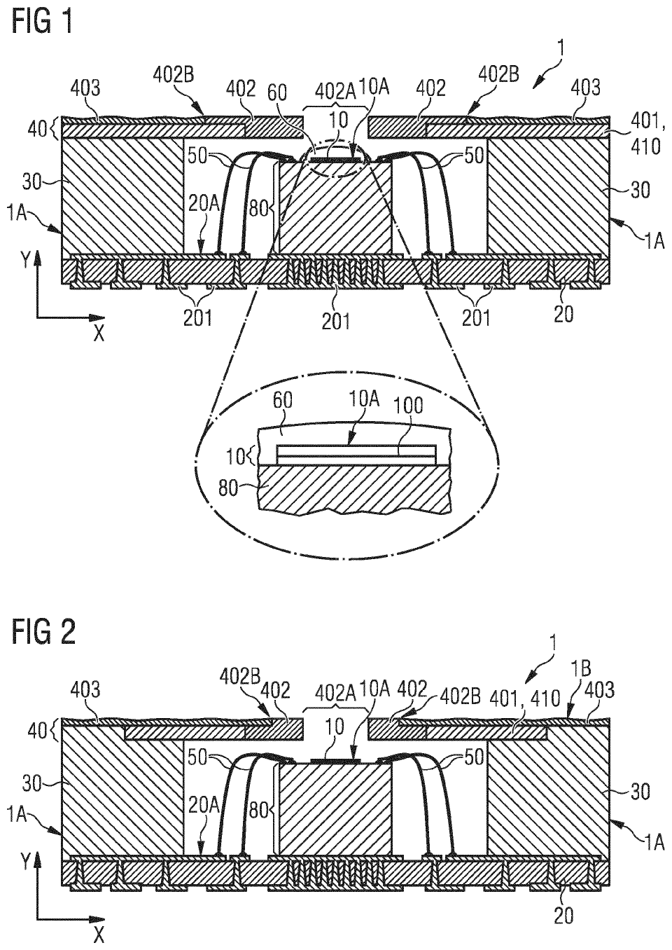

FIG. 1 shows a schematic sectional view of an optoelectronic semiconductor component described here in accordance with a first exemplary embodiment,

FIG. 2 shows a schematic sectional view of an optoelectronic semiconductor component described here in accordance with a second exemplary embodiment,

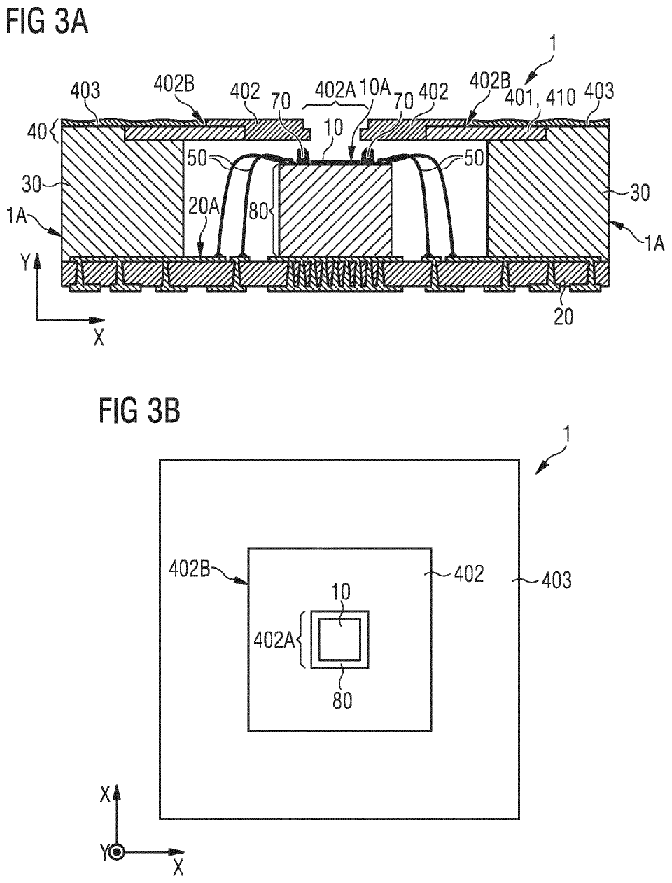

FIG. 3A shows a schematic sectional view of an optoelectronic semiconductor component described here in accordance with a third exemplary embodiment,

FIG. 3B shows a schematic plan view of an optoelectronic semiconductor component described here in accordance with the third exemplary embodiment,

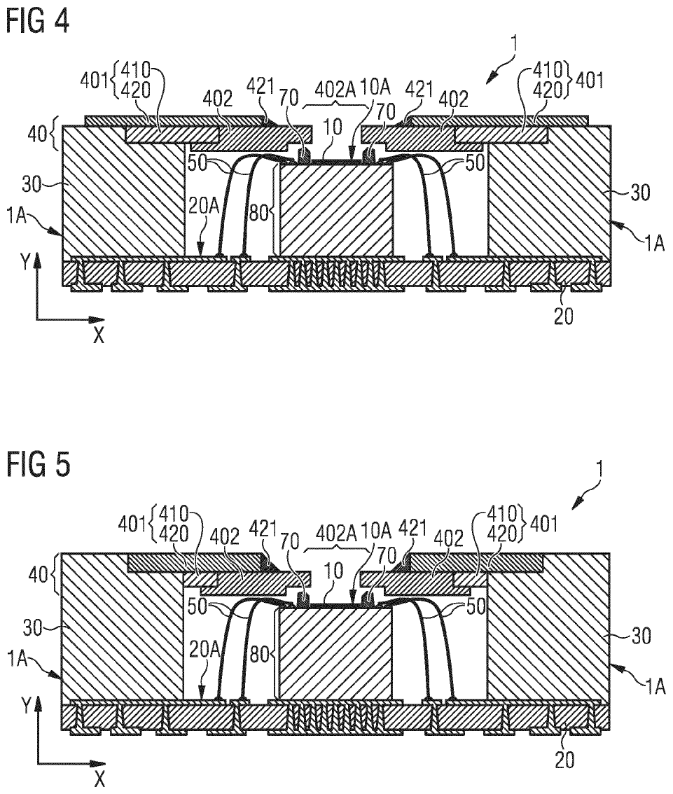

FIG. 4 shows a schematic sectional view of an optoelectronic semiconductor component described here in accordance with a fourth exemplary embodiment,

FIG. 5 shows a schematic sectional view of an optoelectronic semiconductor component described here in accordance with a fifth exemplary embodiment,

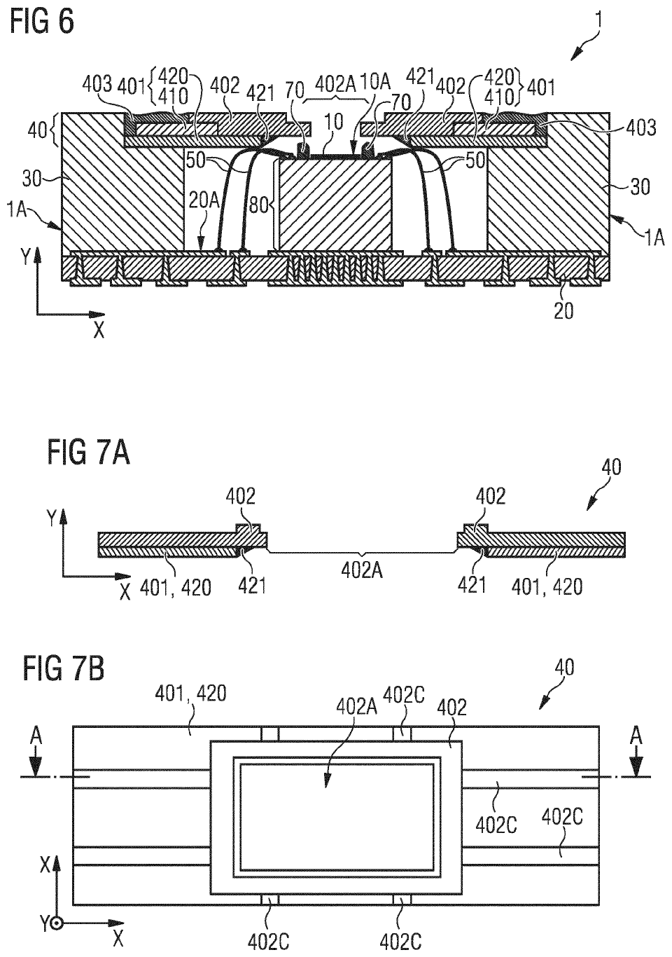

FIG. 6 shows a schematic sectional view of an optoelectronic semiconductor component described here in accordance with a sixth exemplary embodiment,

FIG. 7A shows a schematic sectional view of a prefabricated optical shield described here in accordance with a first exemplary embodiment,

FIG. 7B shows a schematic plan view of a prefabricated optical shield described here in accordance with the first exemplary embodiment,

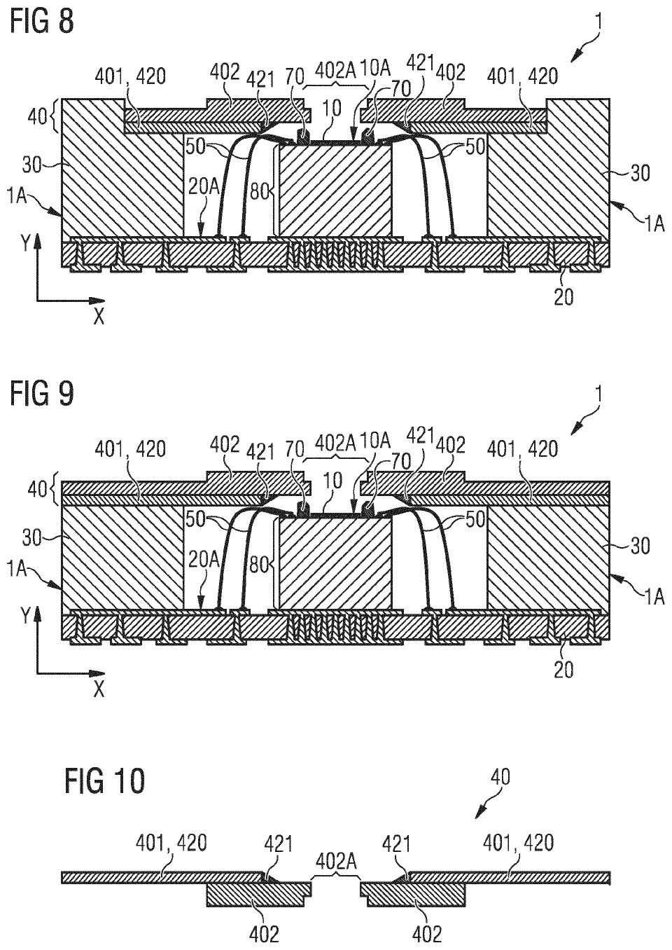

FIG. 8 shows a schematic sectional view of an optoelectronic semiconductor component described here in accordance with a seventh exemplary embodiment,

FIG. 9 shows a schematic sectional view of an optoelectronic semiconductor component described here in accordance with an eighth exemplary embodiment, and

FIG. 10 shows a schematic sectional view of a prefabricated optical shield described here in accordance with a second exemplary embodiment.

Elements that are identical, of identical type or act identically are provided with the same reference signs in the figures. The figures and the size relationships of the elements illustrated in the figures among one another should not be regarded as to scale. Rather, individual elements may be illustrated with an exaggerated size in order to enable better illustration and/or in order to afford a better understanding.

FIG. 1 shows a schematic sectional view of a semiconductor component 1 described here in accordance with the first exemplary embodiment. The optoelectronic semiconductor component 1 comprises a control element 80 and a molded body 30, which are arranged on a front side 20A of a carrier 20. A semiconductor body 10 is arranged on a side of the control element 80 facing away from the carrier 20. A prefabricated optical shield 40 is arranged on a side of the molded body 30 facing away from the carrier 20.

The control element 80 comprises an integrated circuit having a plurality of circuit elements. The control element 80 is provided for electrically controlling the semiconductor body 10. The control element 80 is electrically connected via a plurality of bonding wires 50 to the electrical contact structures 201 on the front side 20A of the carrier 20.

The semiconductor body 10 comprises a plurality of semiconductor layers grown epitaxially one on top of another in a stacking direction. The stacking direction runs transversely with respect to a main extension plane of the semiconductor body 10 and parallel to the extension thereof in a vertical direction Y. The semiconductor body 10 has an optically active region 100 configured for emitting electromagnetic radiation. The active region 100 is discernible in the enlarged detail of the semiconductor body 10. The active region 100 extends along the main extension direction of the semiconductor body 10.

The optically active region 100 is not illustrated in FIGS. 2 to 10, for reasons of clarity.

Furthermore, the semiconductor body 10 comprises a main surface 10A on a side of the semiconductor body 10 facing away from the carrier 20. At least part of the electromagnetic radiation generated in the optically active region 100 during operation leaves the semiconductor body 10 through the main surface 10A.

A conversion element 60 is arranged on the main surface 10A, and is configured for converting electromagnetic radiation of a first wavelength that emerges from the semiconductor body 10 during operation to electromagnetic radiation of a second wavelength. By way of example, the semiconductor body 10 together with the conversion element 60 is configured for emitting mixed radiation that causes a white color impression for an observer. The conversion element 60 is applied on the main surface 10A by means of a spraying method, for example. In particular, the conversion element 60 also covers part of the control element 80.

The molded body 30 completely surrounds the semiconductor body 10 in a lateral direction X. The lateral direction X runs parallel to a main extension plane of the carrier 20 and of the semiconductor body 10 and thus transversely, in particular perpendicularly, with respect to the stacking direction of the semiconductor body 10 and the vertical direction Y. The molded body 30 is formed with a polymer that can be arranged on the carrier 20 by means of a compression molding method or a transfer molding method. Alternatively, the molded body 30 could be embodied beforehand as a continuous, lattice like structure that is applied to the carrier 20. The molded body 30 is, in particular, nontransmissive to electromagnetic radiation generated in the optically active region 100 during operation.

The carrier 20 is preferably a printed circuit board formed with a printed circuit board material and comprises a plurality of contact structures 201. Furthermore, the carrier 20 can be embodied as a leadframe, preferably as a QFN leadframe. Alternatively, the carrier 20 is formed with a ceramic material. The carrier 20 provides a mounting platform for the semiconductor body 10 and the molded body 30, said mounting platform having a sufficient mechanical stability for the optoelectronic semiconductor component 1. The contact structures 201 at least partly penetrate through the carrier 20 in a vertical direction.

By way of example, the prefabricated optical shield 40 is formed with a leadframe. Preferably, the optical shield 40 is formed with a prefabricated QFN leadframe.

The prefabricated optical shield 40 comprises a support structure 401, a diaphragm 402 and a protective layer 403. The diaphragm 402 has an opening 402A aligned with the optically active region 100 of the semiconductor body. The diaphragm 402 partly projects beyond the support structure 403 in the lateral direction, which leads to particularly stable securing of the diaphragm 402 to the support structure 401.

The optical shield 40 partly projects beyond the semiconductor body 10 in the lateral direction. The opening 402A is aligned in such a way that the electromagnetic radiation generated in the semiconductor body 10 during operation can leave the semiconductor component 1 with the least possible obstruction. By means of the optical shield 40, radiation-sensitive parts of the optoelectronic component 1 are protected against insolation, for example. In this regard, a durability of the optoelectronic semiconductor component 1 is advantageously increased.

The support structure 401 comprises a first support element 410, which is formed with an epoxy composite material. The diaphragm 402 is formed with copper and has a projection 402B extending on a side of the diaphragm 402 facing away from the carrier 20 in the vertical direction Y. The projection 402B has an extension of at least 35 μm.

The protective layer 403 is formed with a blackened silicone that protects the underlying support structure 401 against external radiation. The projection 402B of the diaphragm 402 delimits the lateral extent of the protective layer 403 in the direction of the diaphragm 402. A protective layer 403 arranged on the support structure 401 by means of dispensing thus automatically stops at the projection 402B of the diaphragm 402.

The optical shield 40 is able to be fitted on the molded body 30 particularly easily as a prefabricated component. A complex step for mounting the diaphragm 402 on the support structure 401 and for precisely creating the opening 402A can thus advantageously be implemented beforehand in a separate step before the optical shield 40 is mounted on the molded body 30.

The optoelectronic semiconductor component 1 has a side surface 1A composed of partial surfaces of the carrier 20, of the molded body 30 and of the optical shield 40. The side surface 1A delimits the optoelectronic semiconductor component 1 in the extension thereof in the lateral direction X. The side surface 1A is advantageously planar, thereby facilitating mechanical gripping of the optoelectronic semiconductor component 1. Furthermore, components having planar side surfaces 1A can be arranged at a particularly small lateral distance from one another.

FIG. 2 shows a schematic sectional view of a semiconductor component 1 described here in accordance with the second exemplary embodiment. In contrast to the first exemplary embodiment, the optical shield 40 in the second exemplary embodiment shown in FIG. 2 is incorporated into the molded body 30 in flush fashion. Furthermore, the semiconductor component 1 in accordance with the second exemplary embodiment does not comprise a conversion element 60. The molded body 30 has a recess corresponding to at least a vertical extension of the support structure 401. A planar surface 1B of the optoelectronic semiconductor component 1 thus arises. A planar surface 1B facilitates an arrangement of further components on the surface 1B. In this case, the protective layer 403 additionally serves for mechanically securing the optical shield 40 to the molded body 30. An additional adhesive layer can thus be dispensed with.

Furthermore, the diaphragm 402 is secured to the first support element 410 of the support structure 401 by a butt joint. Such securing of the diaphragm 402 is able to be produced particularly easily.

FIG. 3A shows a schematic sectional view of a semiconductor component 1 described here in accordance with the third exemplary embodiment. The third exemplary embodiment substantially corresponds to the second exemplary embodiment shown in FIG. 2. In contrast to the second exemplary embodiment, the diaphragm 402 partly overlaps the first support element 410 of the support structure 401 in the lateral direction X.

Furthermore, a diameter of the opening 402A changes with the distance with respect to the semiconductor body 10. The opening 402A tapers in the direction of the semiconductor body 10. An opening 402A configured in this way produces a diaphragm 402 having an enlarged aperture and thus reduces or avoids shading of electromagnetic radiation passing through it.

Furthermore, the optoelectronic semiconductor component 1, in accordance with the third exemplary embodiment shown in FIG. 3A, comprises a dam structure 70 arranged next to the semiconductor body 10 in a lateral direction X. The dam structure 70 is arranged on the side of the control element 80 facing away from the carrier 20.

The opening 402A has a diameter that increases with increasing distance from the main surface 10A of the semiconductor body 10. Shading of electromagnetic radiation that emerges from the semiconductor body 10, or is incident thereon, by the diaphragm 402 can thus be further reduced or avoided. Preferably, the opening 402A of the diaphragm 402 is already structured before the optical shield 40 is mounted on the molded body 30.

The dam structure 70 is formed with a blackened silicone. The dam structure is nontransmissive to the electromagnetic radiation emitted from the semiconductor body 10 during operation and to electromagnetic radiation incident on the optoelectronic semiconductor component 1 from outside. In this regard, the dam structure 70 protects radiation-sensitive parts of the optoelectronic component 1, for example the molded body 30, the carrier 20 and the support structure 401, both against externally incident electromagnetic radiation and against the electromagnetic radiation emitted in the semiconductor body 10 during operation.

The dam structure 70 forms a closed ring along its extension in the lateral direction X. Furthermore, the dam structure 70 protects the bonding wires 50 arranged on the side of the control element 80 facing away from the carrier 20 against mechanical damage. By way of example, the dam structure 70 is embodied in such a way that it directly touches the optical shield 40. In this regard, the dam structure 70 can serve for supporting the optical shield 40 and can further increase a mechanical stability of the optical shield 40.

FIG. 3B shows a schematic plan view of an optoelectronic semiconductor component 1 described here in accordance with the third exemplary embodiment. The alignment and the extension of the opening 402A in the lateral direction X are readily discernible in the plan view. The opening 402A is aligned with the optically active region 100 arranged below the conversion element 60. The extension of the protective layer 403 is delimited by the projection 402B of the diaphragm 402 in the lateral direction X.

FIG. 4 shows a schematic sectional view of an optoelectronic semiconductor component 1 described here in accordance with the fourth exemplary embodiment. The fourth exemplary embodiment substantially corresponds to the third exemplary embodiment shown in FIG. 3A.

The optical shield 40 in the fourth exemplary embodiment comprises a support structure 401 having a first support element 410 and a second support element 420. The first support element 410 is formed with an epoxy composite material. In particular, the first support element 410 and the diaphragm 402 are part of a prefabricated leadframe composite assembly.

The second support element 420 is formed with a glass fiber-reinforced composite material, preferably an FR4 composite material. The second support element 420 is adhesively bonded to the first support element 410 and the diaphragm 402. Furthermore, the optical shield 40 comprises an encapsulation 421 at the ends of the second support element 420 in a lateral direction. The encapsulation 421 is formed by a polysiloxane. Escape of particles of the glass fibers contained in the second support element can be reduced or avoided by means of the encapsulation 421. Preferably, all outer edges of the second support element 420 are covered with the encapsulation 421 in the lateral direction X.

The second support element 420 is arranged on a side of the first support element 410 and the diaphragm 402 facing away from the carrier 20. In this regard, the first support element 410 can be protected particularly well against electromagnetic radiation that impinges on the optoelectronic semiconductor component 1 from outside. The second support element 420 projects beyond the first support element 410 and the molded body 30 in the lateral direction X. The second support element 420 bears on the molded body 30 on a side of the molded body 30 facing away from the carrier 20.

Furthermore, a diameter of the opening 402A changes with the distance with respect to the semiconductor body 10. The opening 402A widens in the direction of the semiconductor body 10.

FIG. 5 shows a schematic sectional view of an optoelectronic semiconductor component 1 described here in accordance with the fifth exemplary embodiment. The fifth exemplary embodiment substantially corresponds to the fourth exemplary embodiment shown in FIG. 4. In contrast to the exemplary embodiment shown in FIG. 4, the second support element 420 is arranged in a recess of the molded body 30. The extent of the recess in the molded body 30 in the vertical direction corresponds to at least the extent of the second support element 420 in the vertical direction. This results in a planar surface of the optoelectronic semiconductor component 1, on a side opposite the carrier 20.

FIG. 6 shows a schematic sectional view of an optoelectronic semiconductor component 1 described here in accordance with the sixth exemplary embodiment. The sixth exemplary embodiment substantially corresponds to the fifth exemplary embodiment shown in FIG. 5. In contrast to the fifth exemplary embodiment, the second support element 420 is arranged at a side of the optical shield 40 facing the semiconductor body 10.

In this regard, the first support element 410 can be protected particularly well against electromagnetic radiation that emerges from the semiconductor body 10 during operation.

In addition, the optical shield 40 comprises a protective layer 403 arranged on a side of the optical shield 40 facing away from the semiconductor body 10. The protective layer 403 is formed with a blackened silicone and protects the first support element 410 against electromagnetic radiation incident on the optoelectronic semiconductor component 1 from outside. Furthermore, the protective layer 403 serves for mechanically fixing the optical shield 40 on the molded body 30.

FIG. 7A shows a schematic sectional view of a prefabricated optical shield 40 described here in accordance with the first exemplary embodiment. The optical shield 40 comprises a support structure 401 having a second support element 420, a diaphragm 402 and an encapsulation 421. Dispensing with a first support element 410 thus gives rise to a particularly space-saving shield 40. An optical shield 40 embodied in this way is producible for example with a prefabricated QFN leadframe that is adhesively bonded onto a printed circuit board.

The diaphragm 402 extends completely over the second support element 420 along the lateral direction X. The extent of the diaphragm 402 decreases in the vertical direction Y with increasing distance from the opening 402A. The second support structure 420 is formed with a printed circuit board material and has a particularly high thermal stability. During mounting of the prefabricated optical shield 40 illustrated here, the second support element 420 is aligned in a manner facing a carrier 20.

FIG. 7B shows a schematic plan view of an optical shield 40 described here in accordance with the first exemplary embodiment. The sectional view shown in FIG. 7A corresponds to a section from FIG. 7B along the sectional line AA. The diaphragm 402 forms a closed frame around the opening 402A. The diaphragm 402 further comprises thinned struts 402C provided for mechanically securing the diaphragm 402 to the second support element 420. The struts 402C hold the diaphragm 402 prior to mounting of the diaphragm 402 on the second support element 420. In particular, the struts 402C enable an arrangement of a plurality of diaphragms 402 with a fixed pitch. By way of example, the pitch of the diaphragms 402 corresponds to a pitch of recesses in the second support element 420. Advantageously, a plurality of diaphragms 402 can thus be aligned with a plurality of recesses in a second support element 420 in a parallel manner.

On the side of the second support element 420 facing away from the carrier, an interspace situated between the struts 402C can be covered with a metal. By way of example, the metal is copper. Advantageously, a thus increased reflectivity of the optical shield 40 makes it possible to reduce maximum heating as a result of external radiation. In addition, a layer of a metal can bring about dissipation of heat in a larger region. In order to increase an adhesion of the struts 402C on the second support element 420, advantageously, no metal is arranged between the struts 402C and the second support element 420.

FIG. 8 shows a schematic sectional view of an optoelectronic semiconductor component 1 described here in accordance with the seventh exemplary embodiment. The seventh exemplary embodiment substantially corresponds to the sixth exemplary embodiment illustrated in FIG. 6. In contrast to the sixth exemplary embodiment, the optical shield 40 comprises a support structure 401 having only a second support element 420 and without a first support element 410. The second support element 420 is formed with a printed circuit board material.

The diaphragm 402 extends completely over the second support element 420 along the lateral direction X. An optical shield 40 embodied in this way has a particularly small extent in the vertical direction Y.

FIG. 9 shows a schematic sectional view of an optoelectronic semiconductor component 1 described here in accordance with an eighth exemplary embodiment. The eighth exemplary embodiment substantially corresponds to the seventh exemplary embodiment shown in FIG. 8. In contrast to the seventh exemplary embodiment, the optical shield 40 is not arranged in a recess of the molded body 30 on a side of the molded body 30 facing away from the carrier 20.

The optical shield 40 is arranged on the side of the molded body 30 facing away from the carrier 20. A molded body 30 that does not have a recess is advantageously able to be produced particularly easily.

FIG. 10 shows a schematic sectional view of a prefabricated optical shield 40 described here in accordance with the second exemplary embodiment. The second exemplary embodiment substantially corresponds to the first exemplary embodiment shown in FIG. 7A. In contrast to the first exemplary embodiment, upon subsequent mounting of the optical shield 40, the second support element 420 is arranged on a side of the optical shield 40 facing away from the carrier 20. An optical shield 40 embodied in this way is producible for example with a prefabricated QFN leadframe that is adhesively bonded onto a printed circuit board.

The semiconductor bodies 10 shown in FIGS. 1 to 6 and also 8 and 9 are configured for emitting electromagnetic radiation during operation, but all the exemplary embodiments are likewise conceivable for a semiconductor body 10 configured for detecting electromagnetic radiation.

The invention is not restricted by the description on the basis of the exemplary embodiments. Rather, the invention encompasses any novel feature and also any combination of features, which in particular includes any combination of features in the patent claims, even if this feature or this combination itself is not explicitly specified in the patent claims or exemplary embodiments.

### LIST OF REFERENCE SIGNS

1 optoelectronic semiconductor component
1A side surface
1B surface
10 semiconductor body
10A main surface
20 carrier
20A front side
30 molded body
40 optical shield
50 bonding wire
60 conversion element
70 dam structure
80 control element
100 active region
201 contact structure
401 support structure
410 first support element
420 second support element
421 encapsulation
402 diaphragm
402A opening
402B projection
402C strut
403 protective layer
X lateral direction
Y vertical direction

1. An optoelectronic semiconductor component, comprising:
a semiconductor body having an optically active region configured for emitting or detecting electromagnetic radiation,
a carrier,
a molded body, and
a prefabricated optical shield comprising a support structure and a diaphragm, wherein:
the semiconductor body and the molded body are arranged on a front side of the carrier,
the molded body at least partly surrounds the semiconductor body in a lateral direction,
the optical shield is arranged on a side of the molded body facing away from the carrier and projects beyond the molded body in the lateral direction in the direction of the semiconductor body,
the diaphragm has an opening aligned with the optically active region, and
a dam structure is arranged next to the semiconductor body in the lateral direction, and at least partly surrounds the semiconductor body.

2. The optoelectronic semiconductor component as claimed in claim 1,
wherein the optical shield comprises a protective layer arranged on a side of the optical shield facing away from the molded body.

3. The optoelectronic semiconductor component as claimed in claim 2,
wherein the protective layer mechanically connects the optical shield to the molded body.

4. The optoelectronic semiconductor component as claimed in claim 2,
wherein the protective layer is formed with a polysiloxane.

5. The optoelectronic semiconductor component as claimed in claim 1,
wherein the optical shield is incorporated into the molded body in a vertical direction.

6. The optoelectronic semiconductor component as claimed in claim 1,
wherein the dam structure touches a side of the optical shield facing the carrier.

7. The optoelectronic semiconductor component as claimed in claim 1,
wherein the carrier, the molded body and the optical shield form a housing for the optoelectronic semiconductor component.

8. The optoelectronic semiconductor component as claimed in claim 1,
wherein at least one side surface is planar.

9. The optoelectronic semiconductor component as claimed in claim 1,
wherein the support structure is multipartite and comprises a first support element and a second support element.

10. The optoelectronic semiconductor component as claimed in claim 9,
wherein the first support element is formed with an epoxy composite material.

11. The optoelectronic semiconductor component as claimed in claim 9,
wherein the second support element is formed with a printed circuit board material.

12. The optoelectronic semiconductor component as claimed in claim 1,
wherein the diaphragm is formed with copper.

13. The optoelectronic semiconductor component as claimed in claim 1,
wherein the diaphragm has an extent in a vertical direction of at least 50 μm and at most 500 μm, or of at least 100 μm and at most 250 μm.

14. The optoelectronic semiconductor component as claimed in claim 1,
wherein the diaphragm, on a side facing away from the carrier, has a projection above the support structure in a vertical direction.

15. The optoelectronic semiconductor component as claimed in claim 1,
wherein a diameter of the opening changes with a distance with respect to the semiconductor body.

16. A method for producing an optoelectronic semiconductor component, comprising:
providing a carrier together with a semiconductor body having an optically active region configured for emitting or detecting electromagnetic radiation, and together with a molded body on a front side of the carrier, and
arranging a prefabricated optical shield comprising a support structure and a diaphragm on a side of the molded body facing away from the carrier, wherein the diaphragm has an opening aligned with the optically active region, wherein the arranging of the prefabricated shield is preceded by arranging a dam structure next to the semiconductor body in a lateral direction.

17. The method for producing the optoelectronic semiconductor component as claimed in claim 16, further comprising:
applying a protective layer on a side of the optical shield facing away from the carrier.
